(19) United States
(12) Patent Application Publication
(10) Pub. No.: US 2024/0418761 A1
(43) Pub. Date: Dec. 19, 2024

(54) CHARGE MONITORING CIRCUIT

(71) Applicant: ams-OSRAM AG, Premstaetten (AT)

(72) Inventor: Dominik RUCK, Lannach (AT)

(21) Appl. No.: 18/699,596

(22) PCT Filed: Oct. 11, 2022
(86) PCT No.: PCT/EP2022/078171

§ 371 Date: Apr. 9, 2024

(30) Foreign Application Priority Data
Oct. 14, 2021 (GB) 2114714.5

(51) Int. Cl. G01R 29/24; G01S 7/484; G01S 7/497

(52) U.S. Cl. CPC G01R 29/24; G01S 7/484; G01S 7/497

(57) ABSTRACT

A circuit for monitoring an amount of charge provided to at least one radiation-emitting element configured to: determine a charge storage capacity of a charge storage device; measure a first voltage at the charge storage device before the at least one radiation-emitting element is driven; and measure a second voltage at the charge storage device after the at least one radiation-emitting element is driven. The circuit includes processing circuitry configured to determine an amount of charge provided to the at least one radiation-emitting element based on the charge storage capacity and a difference between the first and second voltages.

### RELATED APPLICATION(S)

This application is a US National Stage Application of International Application PCT/EP2022/078171, filed on 11 Oct. 2022, and claims priority under 35 U.S.C. § 119 (a) and 35 U.S.C. § 365 (b) from United Kingdom Patent Application GB 2114714.5, filed on 14 Oct. 2021, the contents of which are incorporated herein by reference in their entirety.

### TECHNICAL FIELD

The present disclosure relates to devices for monitoring an amount of charge provided to radiation-emitting elements such as laser diodes and, in particular, Vertical Cavity Surface Emitting Lasers (VCSELs).

### BACKGROUND

Laser diodes, and in particular VCSELs, are implemented in various optical devices, such as proximity sensors, time-of-flight sensors and infrared illuminators. Such optical devices may be commonly implemented in portable devices such as cellular telephones, tablets, laptops and smartphones, and other industrial and automotive applications, such as in Light Detection and Ranging (LIDAR) systems.

Many applications of laser diodes require precise control over the operation of the laser diode, which may be achieved by a correct and accurate control of a drive current and/or voltage level applied to the laser diode, at an appropriate timing.

Provision of a drive current and/or adequate voltage level may be provided to a laser diode by a driver circuit. Based on particular application requirements, such a driver circuit may be configured to drive one or more laser diodes.

However, existing driver circuits may exhibit several shortcomings that may be detrimental to an application employing such laser diodes, and in particular highly sensitive VCSELs. For example, existing driver circuits may exhibit a limited accuracy and/or stability. This may be due, at least in part, to a susceptibility of components of the circuit and/or of a technology the circuit is implemented in, to various influencing conditions such as environmental conditions and manufacturing process related drift.

Control of a laser diode may be critical in some use cases. For example, in eye-safety applications it may be essential that a provided drive current is sufficient to adequately stimulate a laser diode, yet not exceed a defined threshold that may cause the diode to exceed a radiation threshold, potentially causing eye-damage. In an example, the automotive sector implements strict functional safety standards such as ISO26262, which dictate minimum safety levels that must be adhered to. For example, in an ISO26262 Automotive Safety Integrity Level (ASIL) C compliant system, fail-safe modes of operation may be mandated such that the system reverts to a known safe state in the event of detection of a failure in the system.

Although some laser diode driver circuits may implement some degree of monitoring, such monitoring and any adjustments to the driving of a diode made as a result of said monitoring, may be relatively slow to implement and ineffectual. Existing systems for monitoring operation of driver circuits may be limited in accuracy and may be relatively slow to respond in the event of a failure in the system.

Some existing monitoring systems directly monitor an emitted beam of radiation from the laser diodes. However, such systems may incur losses and may require implementation of moving parts and additional costly and expensive components.

Furthermore, there is a general trend towards implementing increasingly large arrays of laser diodes, such as in VCSEL-based infrared illuminator applications. Existing laser diode driver circuits generally exhibit limited scalability and/or flexibility, and are therefore less suited to such applications.

It is therefore desirable to provide an accurate, low-complexity, and scalable laser diode driver circuit, particularly suitable for driving one or more VCSELs. It is desirable that such a driver circuit has a relatively fast response in the event of a failure condition and is suitable for implementation in ASIL C or ASIL D compliant automotive systems. It is furthermore desirable that an energy of radiation emitted by a laser diode may be monitored without incurring optical losses.

At least one embodiment of at least one aspect of the present disclosure relates to obviating or at least mitigating at least one of the above identified shortcomings.

### SUMMARY

According to a first aspect of the disclosure, there is provided a circuit for monitoring an amount of charge provided to at least one radiation-emitting element. The circuit is configured to: determine a charge storage capacity of a charge storage device; measure a first voltage at the charge storage device before the at least one radiation-emitting element is driven; and measure a second voltage at the charge storage device after the at least one radiation-emitting element is driven.

The circuit comprises processing circuitry configured to determine an amount of charge provided to the at least one radiation-emitting element based on the charge storage capacity and a difference between the first and second voltages.

The disclosed circuit can provide an accurate, low-complexity circuit suitable for monitoring energy provided to at least one radiation-emitting element, e.g. a VCSEL array. Because the circuit determines the charge provided to the at least one radiation-emitting element after each drive cycle, e.g. each pulse, the circuit is adapted to very rapidly respond to any anomalies, e.g. the charge exceeding a predetermined threshold as described in more detail below. This makes the circuit particularly suited to safety applications, for example in ASIL C+ compliant LIDAR systems.

Furthermore, because a single charge storage device, e.g. a capacitor, is used to determine a charge applied to at least one radiation-emitting device, the disclosed solution suitable is scalable for use with any amount of radiation-emitting devices as long as the charge storage device has an adequate charge storage capacity to drive the amount of radiation-emitting devices. This makes the disclosed circuit particularly suitable for use with large arrays of radiation-emitting devices, such as VCSEL arrays that may be implemented in a LIDAR system.

The circuit may be configurable to couple the charge storage device to a supply voltage to recharge the charge storage device between drive cycles.

For example, in some embodiments the circuit may comprise a component or sub circuit, such as for example a switch, a DC-DC boost converter or an LDO, configurable to couple the charge storage device to a supply voltage to recharge the charge storage device between drive cycles. Various embodiments implementing a DC-DC boost converter may be particular efficient and suited to implementation on a monolithic device, e.g. one a single integrated circuit.

That is, between each drive cycle of the at least one radiation-emitting device the charge storage device may be recharged to an initial value, e.g. to a voltage corresponding to a supply rail as described in more detail below.

As described above, the first voltage is a voltage at the charge storage device before the at least one radiation-emitting element is driven, e.g. a voltage drop across the charge storage device before the at least one radiation-emitting element is driven. Similarly, the second voltage is a voltage at the charge storage device after the at least one radiation-emitting element is driven, a voltage drop across the charge storage device after the at least one radiation-emitting element is driven.

The circuit may comprise at least one Analog-to-Digital (ADC) converter configurable to measure the voltage drop across the charge storage device. That is, the circuit may comprise at least one ADC configurable to measure the first and second voltages.

In one example, the ADC may be a multi-channel ADC comprising sample-and-hold circuitry, configured such that a first sample of the first voltage may be held until a second sample of the second voltage is completed, thereby enabling a difference between the first sample and the second sample to be determined.

The circuit may comprise a Charge-to-Digital (CDC) converter configurable to measure the size, e.g. a charge storage capacity, of the charge storage device.

For example, in some embodiments the circuit may comprise first and second comparators, each having a first input coupled to respective first and second reference voltages and each having a second input configured to be selectively coupled to the charge storage device.

The circuit may comprise a current source coupled to the second inputs.

The circuit may comprise a first timer sub-circuit coupled to an output of the first and second comparators and configured to measure a time taken for a change in voltage at the charge storage device to drop from the first reference voltage to the second reference voltage.

The processing circuitry may be configured to determine the charge storage capacity ‘C’ according to the equation:

$$C = ( I * dt ) / {d V}_{1} \qquad Equation ( 1 )$$

wherein ‘I’ is the current from the current source, ‘dt’ is the time and ‘dV₁’ is a voltage difference between the first reference voltage and the second reference voltage.

The circuit may be used with various charge storage devices, e.g. capacitors, in various systems because the circuit is configured to determine a charge storage capacity of any charge storage device to which the circuit is coupled.

The circuit may be configured to periodically determine a charge storage capacity of the charge storage device.

The circuit may compensate for changes in the charge storage capacity of the charge storage device. For example, a charge storage capacity of a capacitor may vary substantially over an operating temperature range of the circuit, e.g. over an automotive temperature range of −40 degrees to +125 degrees Celcius. By repeatedly determining a charge storage capacity of such a capacitor, a system implementing the circuit may effectively adapt to changes in the charge storage capacity.

A rate at which the circuit determines a charge storage capacity of the charge storage device may be configurable. In an example, the circuit may be configured determine a charge storage capacity of the charge storage device once for group of drive cycles of a driver for driving the at least one radiation-emitting element. In a further example, the circuit may be configured determine a charge storage capacity of the charge storage device once every frame, e.g. once every 40 milliseconds, wherein a frame may correspond to an integer amount of drive cycles.

The circuit may comprising a second timer sub-circuit configured to determine an on-time of the at least one radiation-emitting element.

The processing circuitry may be configured to determine an average current provided to the at least one radiation-emitting element by dividing the determined amount of charge by the on-time.

The circuit may comprise a driver configured to drive the at least one radiation-emitting element with current induced by a charge stored in the charge storage device.

The driver may be configured to be regulated by the average current.

In addition to monitoring an amount of charge (or power and/or energy as described in more detail below) provided to the at least one radiation-emitting element, the disclosed circuit may also regulate the driver to maintain the amount of charge within desired bounds and/or below a specified threshold level. This may improve an applicability of the circuit to ASIL C+ compliant systems.

The processing circuitry may comprises an accumulator, integrator or lossy integrator configured to determine a value corresponding to a charge provided to the at least one radiation-emitting element over a period of time. For example, in some embodiments an accumulator or integrator may be implemented, wherein the accumulator or integrator is configured to accumulate a value corresponding to a charge provided to the at least one radiation-emitting element over a period of time. In some example embodiments, a lossy integrator may decrement a value corresponding to a charge provided to the at least one radiation-emitting element over a period of time, e.g. the lossy integrator may exhibit a steady decrease over time.

The period of time may be configurable.

For example, the period of time may equate to a frame, wherein the frame comprises multiple drive cycles of the driver.

The processing circuitry or the accumulator, integrator or lossy integrator, may be configured to ensuring a programmable maximum output energy limit is not exceeded. The processing circuitry may also ensure that a minimum amount of energy is radiated which improves applicability in ASLI C+ systems.

The processing circuitry may be configured to store at least one value corresponding to a power-to-energy conversion factor, e.g. a slope efficiency, of the at least one radiation-emitting element, e.g. of the LEDs or SLEDs (superluminescent diodes).

The at least one value corresponding to a power-to-energy conversion factor may be a user-programmable value, e.g. a value stored in a register, memory or other storage device. As such, the circuit is adaptable for use with a range of different radiation-emitting elements.

The processing circuitry may be configured to determine an energy emitted by the at least one radiation-emitting element by multiplying the determined amount of charge by the at least one value corresponding to the power-to-energy conversion factor.

The processing circuitry may be configured to determine an energy emitted by the at least one radiation-emitting element by multiplying the accumulated charge by the at least one value corresponding to the power-to-energy conversion factor.

The processing circuitry may be configured to compare the accumulated charge or the determined energy to a threshold. The threshold may be a stored value corresponding to a programmable threshold.

An average power or amount of energy within a specified time, e.g. a frame, may be used as an indicator to a system that the driver is operating within a safe range. Furthermore, an average power or amount of energy within a specified time may be used to control the circuit, e.g. revert to a fail-safe mode in the event of an error, as described in more detail below.

According to a second aspect of the disclosure, there is provided a device comprising the circuit according to the first aspect and configurable for coupling to the charge storage device and the at least one radiation-emitting element.

In some examples, the device may be provided as a packaged microchip, e.g. a monolithic chip.

In some examples, the device may be packaged as a Multi-Chip Module (MCM). For example, the circuit according to the first aspect may be implemented on a first chip, and one of more further devices such as a processors may be coupled to the first chip.

According to a third aspect of the disclosure, there is provided a Light Detection and Ranging (LiDAR) system comprising the device according to the second aspect, wherein the device is coupled to a charge storage device and at least one radiation-emitting element and configured to drive the at least one radiation-emitting element

The disclosed LIDAR system may meet stringent eye-safety requirements, and may exhibit fail-safe characteristics as may be required by ASIL C+ compliant systems as defined by ISO26262.

According to a fourth aspect of the disclosure, there is provided a method of monitoring an amount of charge provided to at least one radiation-emitting element, the method comprising:
determining a charge storage capacity of a charge storage device;
measuring a first voltage at the charge storage device before the at least one radiation-emitting element is driven;
measuring a second voltage at the charge storage device after the at least one radiation-emitting element is driven; and
determining an amount of charge provided to the at least one radiation-emitting element based on the charge storage capacity and a difference between the first and second voltages.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed herein. These and other aspects of the present disclosure will now be described, by way of example only, with reference to the accompanying drawings, wherein:

FIG. 1 depicts a device comprising a circuit for monitoring an amount of charge provided to at least one radiation-emitting element according to an embodiment of the disclosure;

FIG. 2 depicts Light Detection and Ranging (LiDAR) system according to an embodiment of the disclosure; and

FIG. 3 depicts a method of monitoring an amount of charge provided to at least one radiation-emitting element, according to an embodiment of the disclosure.

### DETAILED DESCRIPTION OF THE DRAWINGS

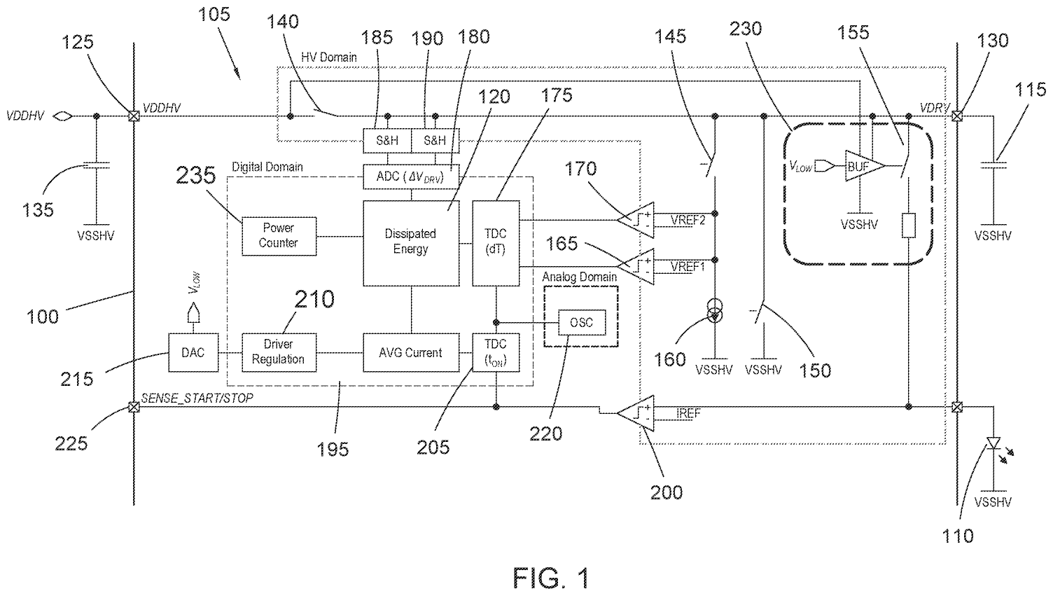

FIG. 1 depicts a device 100 comprising a circuit 105 for monitoring an amount of charge provided to a radiation-emitting element 110 according to an embodiment of the disclosure. The circuit 105 is configured to determine a charge storage capacity of a first charge storage device 115, measure a first voltage at the first charge storage device 115 before the radiation-emitting element 110 is driven, and measure a second voltage at the first charge storage device 115 after the radiation-emitting element 110 is driven. As described in more detail below, the circuit 105 comprises processing circuitry 120 configured to determine an amount of charge provided to the radiation-emitting element 110 based on the charge storage capacity and a difference between the first and second voltages.

For purposes of example only, a single radiation-emitting element 110 is depicted. It will be appreciated that in embodiments falling within the scope of this disclosure, the described circuit 105 and device 100 may be used with a plurality of radiation-emitting elements, e.g. an array of VCSELs.

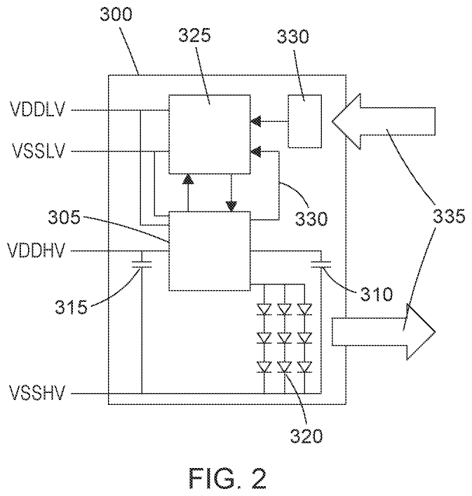

Although the device 100 is depicted as comprising only the circuit 105, it will be understood that the device 100 may comprise further circuitry and/or components that are not depicted, for example further processing circuitry 120 and/or radiation-detection devices or circuitry for controlling or communicating with such radiation-detection devices, as described in more detail with reference to FIG. 2.

In some embodiments, the device 100 may be a microchip, e.g. a packaged integrated circuit. In some embodiments, the device 100 may be provided as in Multi-Chip Module (MCM), e.g. a plurality of microchips coupled in a single package and/or on a common substrate.

The determination of the charge storage capacity of the first charge storage device 115 is as follows.

A high voltage supply, denoted VDDHV, is provided to the circuit 105 via a first pad 125 of the device 100. In some embodiments, a low voltage supply (not shown) may also be provided to the circuit 105, for example to power the processing circuitry 120. In yet further embodiments, one or more regulators internal to the device 100 may generate the low voltage supply from the high voltage supply VDDHV.

Although VDDHV is depicted as supplied only to a single pad, this is for illustrative purposes only and one or more additional pads may also be coupled to VDDHV. Although not shown, it will be understood that a ground reference VSSHV may also be provided to one or more pads. In embodiments, the pads may be bonded or otherwise coupled to a substrate, a printed circuit board, or a pin or ball in a package (not shown).

The first charge storage device 115, which in the example of FIG. 1 is a capacitor, is coupled to a second pad 130 of the device 100. The first charge storage device 115 is external to the device 100.

Furthermore, although first charge storage device 115 is depicted as a single capacitor, it will be appreciated that in embodiments falling within the scope of the disclosure, the first charge storage device 115 may comprise a plurality of capacitors.

A second charge storage device 135, which in the example of FIG. 1 is a bulk capacitor, is coupled to VDDHV. The second charge storage device 135 is external to the device 100.

At an initial time, a first switch 140 in the circuit 105 is closed, coupling the first charge storage device 135 to VDDHV. The first charge storage device 135 is then charged, e.g. by a charge from the second charge storage device 135 coupled to VDDHV, until a voltage at the second pad is equivalent to VDDHV.

Although the ensuing description generally refers to “switches”, it will be appreciated that this is for simplicity of illustration and alternative or more complex circuitry may be implemented that provides switching functionality. For example, the first switch 140 may be implemented as a DC-DC boost convert or an LDO configurable to couple the first charge storage device 135 to a supply voltage such as VDDHV.

Also depicted in the circuit 105 is second switch 145, third switch 150 and fourth switch 155 which are all open at the initial time. Operation of the second switch 145, third switch 150 and fourth switch 155 is described in more detail below.

Next, the first switch 140 is opened, decoupling the first charge storage device 115 from VDDHV. At this time, the first charge storage device 115 is charged to a voltage level of the high voltage supply VDDHV.

The circuit 105 may comprise a Charge-to-Digital (CDC) converter configurable to measure the size, e.g. a charge storage capacity, of the charge storage device. Features and operation of an example embodiment of a CDC as depicted in FIG. 1 in is as follows.

A first comparator 170 has a first input coupled to the second switch 145 and a second input coupled to a first voltage reference denoted VREF1

A second comparator 165 has a first input coupled to the second switch 145 and a second input coupled to a second voltage reference denote VREF2. Voltage reference VREF 2 is at a different voltage level to VREF2.

The first voltage reference VREF1 and the second voltage reference VREF2 may be generated by any known means, e.g. from a bandgap reference or the like.

A current source 160 is coupled between the ground reference VSSHV and the first input of the first comparator 170. The current source 160 is also coupled between the ground reference VSSHV and the first input of the second comparator 165.

A first timer sub-circuit 175 is coupled to an output of the first and second comparators 165, 170.

Next, the second switch 145 is closed and the current source 160 is enabled to allow a known current to flow. At this time, current starts to flow from the first charge storage device 115 and a voltage level at the first charge storage device 115, and hence the first inputs of the first and second comparators 165, 170, begins to drop from VDDHV to a lower voltage level.

The first timer sub-circuit 175 is configured to measure a time taken for a change in voltage at the first charge storage 115 device to drop from the first reference voltage VREF1 to the second reference voltage VREF2.

In the example of FIG. 1, the first timer sub-circuit 175 is a Time-to-Digital Converter (TDC) configured to determine an amount of lapsed time between a first input corresponding to the output of the first comparator 170 being asserted and a second input corresponding to the output of the second comparator 165 being asserted.

After the first timer sub-circuit 175 has determined the amount of lapsed time, ‘dt’, the processing circuitry 120 is configured to determine the charge storage capacity of the first charge storage device 115.

In some embodiments, the processing circuitry 120 may comprise any of: a logic circuit; an Arithmetic Logic Unit (ALU); a central processing unit (CPU); a combinatorial digital circuit; and/or a state machine. In yet further embodiments, processing may be offloaded to an external device, e.g. an external processor or further processing circuitry (not shown in FIG. 1). The processing circuitry 120 may be implemented in the digital domain, e.g. as part of digital circuitry 195.

With knowledge of the voltage levels of VREF1 and VREF 2, a difference in the voltages ‘dV₁’, e.g. VREF2−VREF1, is known. The current ‘I’ flowing through the current source 160 is known. The elapsed time ‘dt’ is determined by the first timer sub-circuit 175. As such, the charge storage capacity ‘C’, e.g. the capacitance, of the first charge storage device 115 is calculated by the processing circuitry 120 according to Equation (1):

$$C = ( I * dt ) / {d V}_{1} \qquad Equation ( 1 )$$

A determination of the charge storage capacity ‘C’ may act as a safety measure. For example, a charge storage capacity ‘C’ having an unexpected value, e.g. greater than or less than a defined threshold, may be indicative of a fault, such as a solder fault or open circuit. In response to detecting that the charge storage capacity ‘C’ is outside predefined bounds, the radiation-emitting element 110 may be disabled, as described in more detail below with reference to the third switch 150.

The ensuing description details use of the determined charge storage capacity ‘C’ to calculate, among other things, an amount of charge provided to the radiation-emitting element 110 following a single drive cycle of a driver 230. However, in various embodiments the circuit 105 may be configured to determine the charge storage capacity ‘C’ at predefined intervals, such as after each drive cycle, each group of drive cycles, each frame corresponding to a plurality of drive cycles, or the like. The circuit 105 may compensate for changes in the charge storage capacity of the first charge storage device 115 due to temperature variations.

Configuration of the circuit 105 to measure the first voltage at the first charge storage device 115 before the radiation-emitting element 110 is driven and the second voltage at the first charge storage device 115 after the radiation-emitting element 110 is driven is now described in more detail.

At a next time, the second switch 145 is opened again and the first switch 140 is closed again, thereby recharging the first charge storage device 115 to the voltage level of the high voltage supply VDDHV. Next, the first switch 140 is opened again, thereby isolating the first charge storage device 115 from the high voltage supply VDDHV.

Next, before the radiation-emitting element 110 is driven, an analog-to-digital converter (ADC) 180 is configured to sample the voltage level at the first charge storage device 115.

In the example embodiment of FIG. 1, the ADC 180 comprises a first channel 185 configured to sample and hold the voltage level at the first charge storage device 115.

An example driver 230 is depicted. The example driver 230 comprises the fourth switch 155 for coupling the first charge storage device 115 to the radiation-emitting element 110. The fourth switch 155 is controlled by a buffer which can be enabled or disabled by the processing circuitry 120 to close or open the fourth switch 155, as will be described in more detail below.

Next, the driver 230 is configured to close the fourth switch 155 to drive the radiation-emitting element 110 with a pulse, thereby depleting a charge stored in the first charge storage device 115, and then reopen the fourth switch 155.

A time that the driver 230 holds the fourth switch 155 closed defines a drive cycle of the driver, e.g. a duration of a pulse of the radiation-emitting element 110. For example, in a LiDAR use case the driver 230 may be configured to drive the radiation-emitting element 110, e.g. hold fourth switch 155 closed, for between 1 nanoseconds and 10 nanoseconds, and with a duty cycle of less than 10%. A particular pulse length and/or duty cycle may be defined based upon particular application requirements.

Next, the ADC 180 is configured to sample the voltage level at the first charge storage device 115 again. In the example of FIG. 1, the ADC 180 comprises a second channel 190 configured to sample and hold the voltage level at the first charge storage device 115. In some examples, a delay may be inserted before sampling and holding the voltage level at the first charge storage device 115 for a second time, to ensure any noise and/or ringing in the circuit 105 has settled.

Next, the ADC and/or the processing circuitry 120 is configured to determine a difference ‘dV₂’ between the voltage at the charge storage device before and after the radiation-emitting element 110 is driven by calculating the difference between the voltage levels held by the first channel 185 and the second channel 190.

The processing circuitry 120 is configured to determine an amount of charge ‘Q’ provided to the radiation-emitting element 110 based on the determined charge storage capacity ‘C’ and the determined difference dV₂ between the first and second voltages. The processing circuitry 120 is configured to solve Equation (2) to determine the amount of charge ‘Q’, wherein:

$$Q = C * {d V}_{2} \qquad Equation ( 2 )$$

As such, the disclosed circuit 105 is capable of accurately determining an amount of charge Q provided to the radiation-emitting element 110 in a single pulse and, as described in more detail below, the disclosed circuit 105 may use knowledge of the amount of charge Q to control the driver 230 and/or configure various safety features.

For example, in some embodiments the circuit 105 may comprise a comparator 200 and a second timer sub-circuit 205 configured to determine a precise on-time of the radiation-emitting element 110.

A first input of the comparator 200 is coupled to an output of the driver 230, e.g. to the radiation-emitting element 110. A second input of the comparator 200 is coupled to a reference current, denoted IREF.

The second timer sub-circuit 205, which in the example embodiment also comprises a time to digital converter (TDC), is configured to count a duration when the comparator 200 indicates that a current greater than IREF is flowing from the driver circuit 230, e.g. the radiation-emitting element 110 is a laser diode in the ‘on’ state and emitting radiation. By directly measuring the on-time, T_{ON}, of the radiation-emitting element 110, any delays in the circuit 105 such as switching time of the driver 230 or delays due to any impedance in a path to the radiation-emitting element 110 may be accounted for.

An output of the comparator 200 also provides a sense signal 225 which may provide an indication to an external device of precise on and off times of the radiation-emitting element 110.

Using the amount of charge ‘Q’ and the on-time T_{ON}, the processing circuitry 120 may be configured to determine an average current, I_{AVG}, provided to the radiation-emitting element 110 by solving Equation (3):

$${I}_{AVG} = Q / {T}_{ON} . \qquad Equation ( 3 )$$

The described circuit 105 is able to accurately determine the average current I_{AVG}, which is otherwise difficult to accurately measure directly.

In some example embodiments, the calculated average current I_{AVG} may be used to regulate the driver 230. For example, a driver regulation subcircuit 210 may compare the calculated average current I_{AVG} to a desired average current and configure a Digital-to-Analog Converter (DAC) 215 to control the above-described buffer of the driver 230 to adjust timings of the fourth switch 155.

As a further safety measure, if the processing circuitry 120 determines that the calculated average current I_{AVG} exceeds a threshold, then the third switch 150 may be closed and the first switch 140 maintained open, effectively discharging the first charge storage device 115 to the ground reference VSSHV. This may provide fail-safe functionality as required by some ASIL C+ compliant automotive systems.

In the depicted embodiment, an oscillator 220 provides a common clock source to both the first timer sub-circuit 175 and the second timer sub-circuit 205, thus minimising any errors in the circuit 105.

In example embodiments, the processing circuitry 120 may comprises an accumulator, integrator or lossy integrator configured to determine a value corresponding to a charge provided to the radiation-emitting element 110 over a period of time. For example, in some embodiments an accumulator or integrator may be implemented, wherein the accumulator or integrator is configured to accumulate a value corresponding to a charge provided to the at least one radiation-emitting element over a period of time. In some example embodiments, a lossy integrator may decrement a value corresponding to a charge provided to the at least one radiation-emitting element over a period of time, e.g. the lossy integrator may exhibit a steady decrease over time.

In the example embodiment of FIG. 1, the processing circuitry 120 may be configure to accumulate a value corresponding to charge provided to the radiation-emitting element 110 over a period of time. In some embodiments the period of time may be configurable, e.g. user programmable. For example, the processing circuitry 120 may comprise a counter 235, which may act as an integrator configured to accumulate the value corresponding to the total charge provided to the radiation-emitting element 110 over the period of time.

Furthermore, the processing circuitry 120 may be configured to store a user programmable parameter corresponding to a slope-efficiency of the radiation-emitting element 110.

In an example embodiment, the processing circuitry 120 is configured to multiply the value corresponding to the accumulated charge by a power-to-energy conversion factor, e.g. a slope efficiency, to determine a total energy dissipated by the radiation-emitting element 110. That is, the accumulated charge, Q_{ACC}, which has units of Coulombs and the Slope Efficiency, S_{EFF}, of the radiation-emitting element 110 which has units of Watts-per-Amp can be multiplied according to Equation (4) to define a dissipated energy, E_{DISS}, in units of Joules.

$${E}_{DISS} = {Q}_{ACC} \times {S}_{EFF} \qquad Equation ( 4 )$$

In some embodiments, the calculated dissipated energy E_{DISS} may be compared to a threshold value, such as a user programmable threshold value. If the calculated E_{DISS} exceeds the threshold value then the third switch 150 may be closed and the first switch 140 held open, effectively discharging the first charge storage device 115 to the ground reference VSSHV. This may provide fail-safe functionality as required by some ASIL C+ compliant automotive systems.

In some embodiments, the processing circuitry 120 may be configured to regulate the driver 230 based on the calculated dissipated energy E_{DISS} and/or the average current I_{AVG}.

FIG. 2 depicts LiDAR system 300 according to an embodiment of the disclosure. The LiDAR system 300 comprises a device 305, wherein the device 305 comprises the circuit according to the embodiment described above with respect to FIG. 1.

Also depicted is a first charge storage device 310 and a second charge storage device 315 coupled to the device 305. The first charge storage device 310 and the second charge storage device 315 may correspond to the first charge storage device 115 and the second charge storage device 135 of FIG. 1 respectively.

For purposes of example only, a VCSEL array 320 is depicted. Although only 9 VCSELs are depicted, it will be understood that this is for purposes of illustration only and a practical LIDAR system 300 may have hundreds or even thousands of VCSELs. The VCSEL array 320 may correspond to the radiation-emitting element 110 of FIG. 1.

Also depicted in FIG. 2 is a further processing device 325. The further processing device 325 is communicably coupled to the device 305 and may comprise any of: a logic circuit; an ALU; a CPU; a combinatorial digital circuit; and/or a state machine. In some examples, a time-base may be shared between the device 305 and the further processing device 325.

A sense signal 330 is provided from the device 305 to the further processing device 325. The sense signal 330 may correspond to the sense signal 225 of the circuit 105 of FIG. 1. That is, the sense signal 330 may provide an indication of a precise on and off times of the VCSEL array 320.

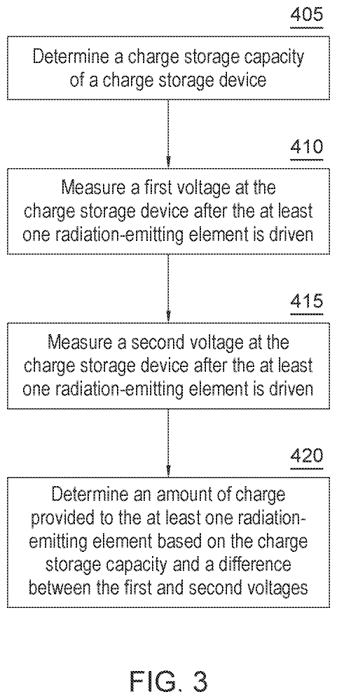

Also depicted in FIG. 3 is a radiation detector 330. The radiation detector 330 may, for example, comprise an array of Single Photon Avalanche Diodes (SPADs) and may be configured to detect radiation 335 emitted from the VCSEL array 320 and reflected from a target.

The further processing device 325 may be configured to determine an indirect and/or direct Time-of-Flight using the sense signal 330 to indicate a transmit time or radiation and one or more signals from the radiation detector 330 to indicate a receive time of reflected radiation.

It will be approached that in other embodiments of the disclosure, some or all of the further processing device 325 may be integrated into the device 305 and/or the radiation detector 330.

FIG. 3 depicts a method of monitoring an amount of charge provided to at least one radiation-emitting element, according to an embodiment of the disclosure.

In a first step 405, a charge storage capacity of a charge storage device may be determined. The determination may, for example, be made as described above with reference to FIG. 1, e.g. using an elapsed time for a voltage at the charge storage device to drop between two known reference voltages, and using Equation (1).

In a second step 410, a first voltage at the charge storage device is measured before the at least one radiation-emitting element is driven. In a third step 415 a second voltage at the charge storage device is measured after the at least one radiation-emitting element is driven. Measurement of the first and second voltages may be made using an ADC comprising sample and hold functionality, as described above with reference to FIG. 1.

In a fourth step 420 an amount of charge provided to the at least one radiation-emitting element is determined based on the charge storage capacity and a difference between the first and second voltages. That is, the charge storage capacity may be calculated by multiplying the difference between the first and second voltages by the charge storage capacity, as defined by Equation (2).

Although the disclosure has been described in terms of particular embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

REFERENCE NUMERALS

| | |
|---|---|
| 100 | device |
| 105 | circuit |
| 110 | radiation-emitting element |
| 115 | first charge storage device |
| 120 | processing circuitry |
| 125 | first pad |
| 130 | second pad |
| 135 | second charge storage device |
| 140 | first switch |
| 145 | second switch |
| 150 | third switch |
| 155 | fourth switch |
| 160 | current source |
| 165 | second comparator |
| 170 | first comparator |
| 175 | first timer sub-circuit |
| 180 | ADC |
| 185 | first channel |
| 190 | second channel |
| 195 | digital circuitry |
| 200 | comparator |
| 205 | second timer sub-circuit |
| 210 | driver regulation sub-circuit |
| 215 | DAC |
| 220 | oscillator |
| 225 | sense signal |
| 230 | driver |
| 235 | counter |
| 300 | LIDAR system |
| 305 | device |
| 310 | first charge storage device |
| 315 | second charge storage device |
| 320 | VCSEL array |
| 325 | further processing device |
| 330 | sense signal |
| 335 | radiation |
| 405 | first step |
| 410 | second step |
| 415 | third step |
| 420 | fourth step |

What is claimed is:

1. A circuit for monitoring an amount of charge provided to at least one radiation-emitting element, the circuit configured to:
determine a charge storage capacity of a charge storage device;
measure a first voltage at the charge storage device before the at least one radiation-emitting element is driven; and
measure a second voltage at the charge storage device after the at least one radiation-emitting element is driven;
wherein the circuit comprises processing circuitry configured to determine an amount of charge provided to the at least one radiation-emitting element based on the charge storage capacity and a difference between the first and second voltages.

2. The circuit of claim 1, configurable to couple the charge storage device to a supply voltage to recharge the charge storage device between drive cycles.

3. The circuit of claim 1, comprising at least one Analog-to-Digital Converter, ADC, configurable to measure the first and second voltages.

4. The circuit of claim 1, comprising a Charge-to-Digital (CDC) converter configurable to measure a charge storage capacity of the charge storage device.

5. The circuit of claim 4, wherein the CDC comprises:
first and second comparators, each having a first input coupled to respective first and second reference voltages and each having a second input configured to be selectively coupled to the charge storage device;
a current source coupled to the second inputs;
a first timer sub-circuit coupled to an output of the first and second comparators and configured to measure a time taken for a change in voltage at the charge storage device to drop from the first reference voltage to the second reference voltage.

6. The circuit of claim 5, wherein the processing circuitry is configured to determine the charge storage capacity ‘C’ according to the equation:
$$C = ( I * dt ) / {d V}_{1}$$
wherein: ‘I’ is the current from the current source; ‘dt’ is the time; and dV₁ is a voltage difference between the first reference voltage and the second reference voltage.

7. The circuit of claim 1, wherein the circuit is configured to periodically determine a charge storage capacity of the charge storage device.

8. The circuit of claim 1, comprising a second timer sub-circuit configured to determine an on-time of the at least one radiation-emitting element.

9. The circuit of claim 8, wherein the processing circuitry is configured to determine an average current provided to the at least one radiation-emitting element by dividing the determined amount of charge by the on-time.

10. The circuit of claim 1, comprising a driver configured to drive the at least one radiation-emitting element with current induced by a charge stored in the charge storage device.

11. The circuit of claim 10, where the driver is configured to be regulated by the average current.

12. The circuit of claim 1, wherein the processing circuitry comprises an accumulator, integrator, or lossy integrator configured to determine a value corresponding to a charge provided to the at least one radiation-emitting element over a period of time.

13. The circuit of claim 12, wherein:
the processing circuitry is configured to store at least one value corresponding to a power-to-energy conversion factor of the at least one radiation-emitting element; and
wherein the processing circuitry is configured to determine an energy emitted by the at least one radiation-emitting element by multiplying the determined amount of charge or the accumulated charge by the at least one value corresponding to the power-to-energy conversion factor.

14. The circuit of claim 13, wherein the processing circuitry is configured to compare the accumulated charge or the determined energy to a stored value corresponding to a programmable threshold.

15. A device comprising the circuit of claim 1 and configurable for coupling to the charge storage device and the at least one radiation-emitting element.

16. A Light Detection and Ranging (LiDAR) system comprising the device of claim 15, wherein the device is coupled to a charge storage device and at least one radiation-emitting element and configured to drive the at least one radiation-emitting element.

17. A method of monitoring an amount of charge provided to at least one radiation-emitting element, the method comprising:
determining a charge storage capacity of a charge storage device;
measuring a first voltage at the charge storage device before the at least one radiation-emitting element is driven;
measuring a second voltage at the charge storage device after the at least one radiation-emitting element is driven; and
determining an amount of charge provided to the at least one radiation-emitting element based on the charge storage capacity and a difference between the first and second voltages.
